(19) United States
(12) Patent Application Publication
(10) Pub. No.: US 2007/0068447 A1
(43) Pub. Date: Mar. 29, 2007

(54) Method of manufacturing silicon wafer

(75) Inventors: Koji Izunome, Shibata-shi (JP); Yumiko Hirano, Kitakanbaragun (JP); Takashi Watanabe, Hiratsuka-shi (JP); Kazuhiko Kashima, Odawara-shi (JP); Hiroyuki Saito, Kitakanbaragun (JP); Takeshi Senda, Kitakanbaragun (JP)

Correspondence Address: FOLEY AND LARDNER LLP;SUITE 500, 3000 K STREET NW, WASHINGTON, DC, 20007, US

(73) Assignee: TOSHIBA CERAMICS CO., LTD.

(21) Appl. No.: 11/526,868

(22) Filed: Sep. 26, 2006

(30) Foreign Application Priority Data
Sep. 27, 2005 (JP) 2005-279049
Jun. 2, 2006 (JP) 2006-154205

(51) Int. Cl. C30B 15/00; C30B 21/06; C30B 27/02; C30B 28/10; C30B 30/04

(52) U.S. Cl. 117/13

(57) ABSTRACT

In order to control a crystal defective area, to inhibit slip generation at the time of annealing treatment, and to manufacture a high quality silicon wafer of high strength with sufficient yields, a method of manufacturing a silicon wafer is provided in which a silicon single crystal is grown by way of Czochralski method under conditions where an oxygen concentration is 0.9×10¹⁸ atoms/cm³ or more and an oxidization induced stacking fault density is the maximum in an area within 20 mm of a wafer circumference, and an as-grown defect density of the wafer obtained by slicing the silicon single crystal is 1×10⁷/cm³ or more over the whole region of the wafer.

### CROSS-REFERENCE TO RELATED PATENT APPLICATIONS

The right of foreign priority is claimed under 35 U.S.C. § 119(a) based on Japan Application No. 2005-279049, filed Sep. 27, 2005, the entire contents of which, including the specification, drawings, claims and abstract, are incorporated herein by reference. The right of foreign priority is also claimed under 35 U.S.C. § 119(a) based on Japan Application No. 2006-154205, filed Jun. 2, 2006, the entire contents of which, including the specification, drawings, claims and abstract, are incorporated herein by reference.

### BACKGROUND OF THE INVENTION

The present invention relates to a method of manufacturing a high quality silicon wafer obtained from a silicon single crystal by way of Czochralski (CZ) method and suitable for a high temperature heat treatment.

When growing a silicon single crystal by way of the CZ method, since a heat history and a shape of a solid/liquid interface of the crystal, a convection speed of a melted material, etc., differ according to a radial direction of the crystal, crystal characteristics of a wafer obtained by slicing the single crystal may be uneven within a face.

For example, a circle-like stacking fault (OSF) concentric with a crystal axis may take place due to oxidization, which is referred to as an oxidization induced stacking-fault ring (R-OSF).

A distribution state of point crystal defects in an axial section of the silicon single crystal is shown in FIG. 1.

As shown in FIG. 1, in the silicon single crystal grown by way of the CZ method, there is an R-OSF area A at a boundary between a V-rich area B where defects (cavity type defects) 1 originated from cavities exist and an I-rich area C where dislocation loops or clusters (silicon type defects between lattices) 2 take place due to excessive silicon between lattices.

Further, an N (Neutral) area where there is substantially no defect may be generated when concentrations of the cavities and the silicon between the lattices are in balance.

The dislocation loops or clusters existing in the above-mentioned I-rich area C may be a cause of reducing yield of a device manufactured from the silicon single crystal.

Similarly, also when there is the R-OSF on a wafer surface, the yield of the device is reduced.

Therefore, with respect to an uneven crystal defective area as shown in FIG. 1, as a means for obtaining a high quality silicon wafer by smoothing the area, a method has been conventionally used in which the R-OSF's are driven out towards the outer circumference over the whole crystal length by raising a crystal pulling speed and by optimizing the heat history by way of adjustment of a ratio v/G between a crystal pulling speed v and a temperature gradient G in a crystal orientation at the outermost circumference so that the whole surface of the wafer obtained from the single crystal may be a V-rich area.

Further, since atoms on the surface of the wafer are re-arranged by way of heat treatment at a high temperature of 1000-1200° C. in an atmosphere, such as hydrogen, argon gas, the above-mentioned R-OSF itself can be eliminated together with the cavity (void) defects of the wafer surface part.

Thus, another method is also used in which the R-OSF is left in the wafer side, then a high temperature heat treatment is carried out (see, for example, Japanese Patent Publication (KOKAI) No. 2000-154095 and Japanese Patent Publication (KOKAI) No. 2003-249501).

Now, in the high temperature heat treatment as mentioned above, oxygen of the wafer surface part externally diffuse, and an oxygen deposit disappears. On the other hand, excessive oxygen between lattices is deposited in bulk. Since the oxygen deposit in this bulk may be a gettering site with respect to metal contamination in a later device manufacturing process, it is preferable that there is the oxygen deposit to some extent. In this respect, the above-mentioned high temperature heat treatment is also effective.

### SUMMARY OF THE INVENTION

As for the raised crystal pulling speed in a process of growing the single crystal as mentioned above and optimization of the heat history, it is becoming difficult to control the heat history as the single crystal is increased in diameter according to recent demands. Thus, the crystal defective area is difficult to smooth by such a process.

On the other hand, a problem arises in that a slip may easily take place in the high temperature heat treatment (annealing treatment) at 1000-1200° C., as mentioned above. In particular, stress may easily take place in a position where the wafer is supported by a boat, thus a slip is probably generated.

In order to prevent such a slip, it is considered to improve a boat form which is not easily stressed, optimize a heat treatment temperature and a rise-and-fall speed in temperature, etc. Further, a single crystal which is hard to generate a slip is also required to develop.

In other words, in order to improve quality of the silicon wafer, it is required not only to control the crystal defective area but also to prevent the slip from taking place at the time of annealing treatment.

In addition, the above-mentioned Japanese Patent Publication (KOKAI) No. 2000-154095 does not disclose any relationship between the slip occurrence prevention and the crystal defective area at the time of the annealing treatment as mentioned above.

Further, as a silicon wafer which is not easy to generate slip dislocation, the above-mentioned Japanese Patent Publication (KOKAI) No. 2003-249501 discloses a wafer having no R-OSF area in a portion located between the outermost circumference part and a tip of a holding means, such as a boat, to which a strong load is applied, and further having a bulk micro defect (BMD) density of 1×10⁹/cm³ or more. However, as such a wafer, depending on an embodiment of the holding means, the slip generation is not always sufficiently inhibited, and its strength is not sufficient either.

The present invention has been made in order to solve the above-mentioned technical problems and aims to provide a method in which a crystal defective area is controlled, slip generation at the time of annealing treatment is inhibited, and a high quality silicon wafer having high strength can be manufactured with sufficient yields.

According to the present invention, there is provided a method of manufacturing a silicon wafer, characterized in that under conditions where an oxygen concentration is 0.9×10¹⁸ atoms/cm³ or more and an oxidization induced stacking fault (OSF) density is the maximum in an area within 20 mm of a wafer circumference, a silicon single crystal is grown by way of Czochralski (CZ) method and an as-grown defect density in the wafer obtained by slicing the above-mentioned silicon single crystal is 1×10⁷/cm³ or more over the whole region of the wafer.

In this way, the silicon wafer having a slip inhibition effect at the time of annealing treatment can be obtained by controlling the as-grown defect density in the silicon wafer.

When the above-mentioned silicon single crystal is grown, it is preferable to cause the OSF's to exist up to the outermost circumference part of the wafer.

In this way, the BMD density due to the oxygen deposit at the circumference part of the wafer after the heat treatment can be made high, whereby it is possible to raise the wafer strength.

Further, when growing the above-mentioned silicon single crystal, the ratio v/G between the crystal pulling speed v (mm/min) and the temperature gradient G (mm/° C.) in the crystal orientation at the outermost circumference is preferably set as 0.190 (mm²/(min.° C.)) or more.

As mentioned above, in order to cause the OSF density to be the maximum in the area within 20 mm of the outer circumference of the wafer, it is preferable to pull up the single crystal on such conditions.

Further, it is preferable that after mirror finish, the above-mentioned silicon wafer is heat treated at a temperature of 1000-1200° C. in a hydrogen or inactive gas atmosphere.

By applying such a high temperature heat treatment to the silicon wafer having the slip inhibition effect, the R-OSF can be eliminated and it is possible to obtain a wafer of high strength.

Especially, the above-mentioned heat treatment is more preferably a hydrogen annealing treatment at a temperature of 1000-1200° C. or a high temperature rapid acceleration Ar annealing treatment.

As described above, according to the method of manufacturing the silicon wafer in accordance with the present invention, the slip generation at the time of the annealing-treatment is inhibited by controlling the crystal defective area, and the silicon wafer of high strength can be obtained.

Therefore, according to the present invention, it is possible to provide the high quality silicon wafer with the sufficient yields, leading to contributions to reduction of costs in manufacturing the devices and improvement in quality.

### BRIEF DESCRIPTION OF THE DRAWINGS

FIG. 1 is a longitudinal sectional view schematically showing a point defect distribution in a silicon single crystal;

FIG. 2 is a graph showing in-plane distributions of OSF's and as-grown defects in a silicon wafer before annealing treatment;

FIG. 3 is a graph showing a relationship (annealing conditions: 1200° C., one hour, hydrogen annealing, vertical furnace, batch processing) between as-grown defect densities of the outermost circumference and slip generation frequencies at the time of annealing in the silicon wafer where an oxygen concentration is 0.9×10¹⁸ atoms/cm³ and R-OSF's exist in a plane;

FIG. 4 is a graph showing a relationship (annealing conditions: 1200° C., 1 msec, high temperature rapid acceleration Ar annealing treatment, sheet-fed processing) between the as-grown defect densities of the outermost circumference and the slip generation frequencies at the time of annealing in the silicon wafer where the oxygen concentration is 0.9×10¹⁸ atoms/cm³ and R-OSF's exist in the plane; and

FIG. 5 is a graph showing a relationship between the as-grown defect densities of the outermost circumference of the silicon wafer and R-OSF peak positions where the oxygen concentration is 0.9×10¹⁸ atoms/cm³ and R-OSF's exist in the plane.

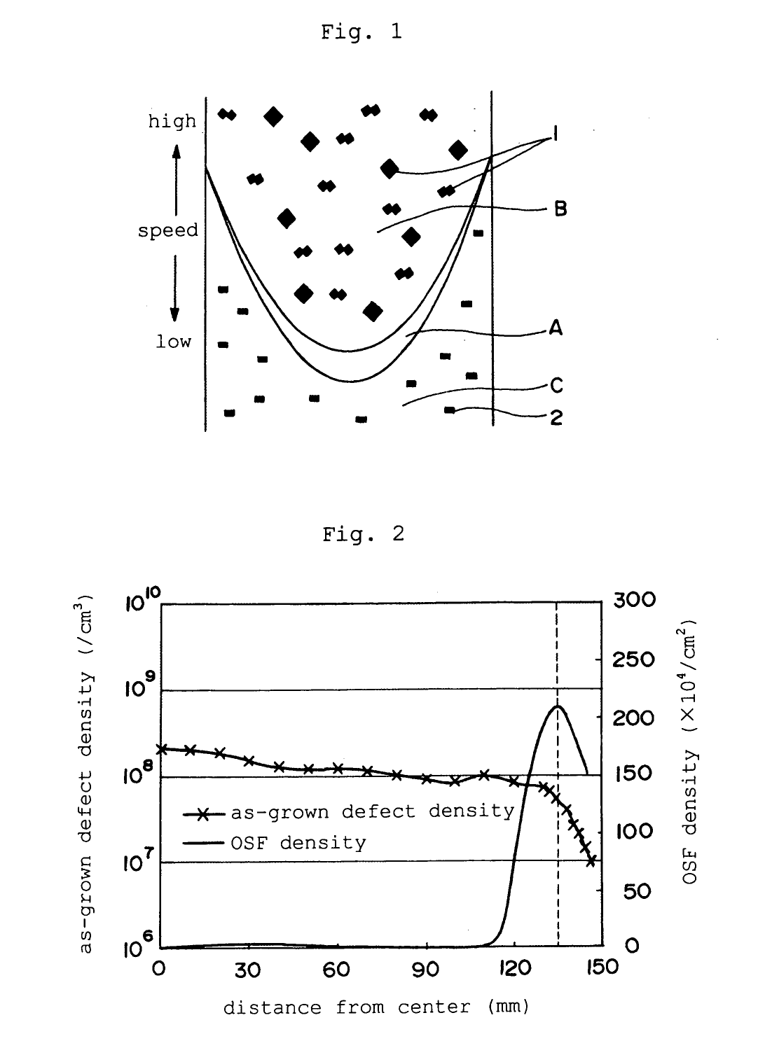

### DETAILED DESCRIPTION OF THE PREFERRED EMBODIMENTS

The present invention will be described in detail hereafter.

In a method of manufacturing a silicon wafer in accordance with the present invention, a silicon single crystal is grown by way of Czochralski (CZ) method under conditions where an oxygen concentration is 0.9×10¹⁸ atoms/cm³ or more and an oxidization induced stacking fault (OSF) density is the maximum in an area within 20 mm of a wafer circumference, and the silicon wafer whose as-grown defect density is 1×10⁷/cm³ or more over the whole region of the wafer is obtained from the silicon single crystal.

By controlling the as-grown defect density in the silicon wafer in this way, the silicon wafer is obtained, having the dislocation (slip) inhibition effect at the time of the high temperature heat treatment (annealing treatment).

Furthermore, it is preferable that OSF's are controlled to exist up to the outermost circumference part of the wafer in the case of the above-mentioned silicon single crystal growth.

By controlling R-OSF to have a width as mentioned above, the as-grown defect density can be set as 1×10⁷/cm³ or more also in the circumference part which has the minimum as-grown defect density in the wafer plane.

Further, the wafer having left R-OSF in the wafer plane may have the BMD density by the oxygen deposit in the circumference part of the wafer after heat treatment, which is higher than that of the wafer having completely driven out R-OSF to the circumference. Therefore, such existence of the BMD can raise the wafer strength.

FIG. 2 shows an in-plane distribution of the as-grown defects in the wafer (300 mm in diameter) before the high temperature heat treatment, where R-OSF's exist.

In addition, this as-grown defect distribution is measured by means of an infrared tomographic apparatus (MO-441, manufactured by Mitsui Mining and Smelting Co., Ltd.)

As shown in the graph of FIG. 2, it can be seen that the as-grown defect distribution is the maximum value in the central part of the wafer and decreases considerably at the circumference part bordering a position where the OSF density is the maximum value (hereafter referred to as R-OSF peak position).

After the mirror finish, the above-mentioned silicon wafer is preferably heat treated at the temperature of 1000-1200° C. in an inactive gas atmosphere, such as hydrogen or argon.

By way of such a high temperature heat treatment, R-OSF can also be eliminated with respect to the silicon wafer having the slip inhibition effect, and it is possible to provide a silicon wafer of a higher quality.

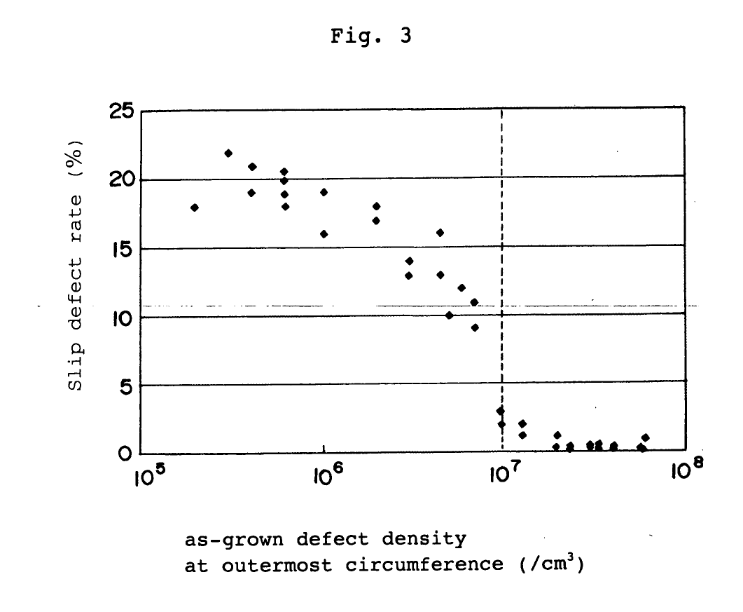

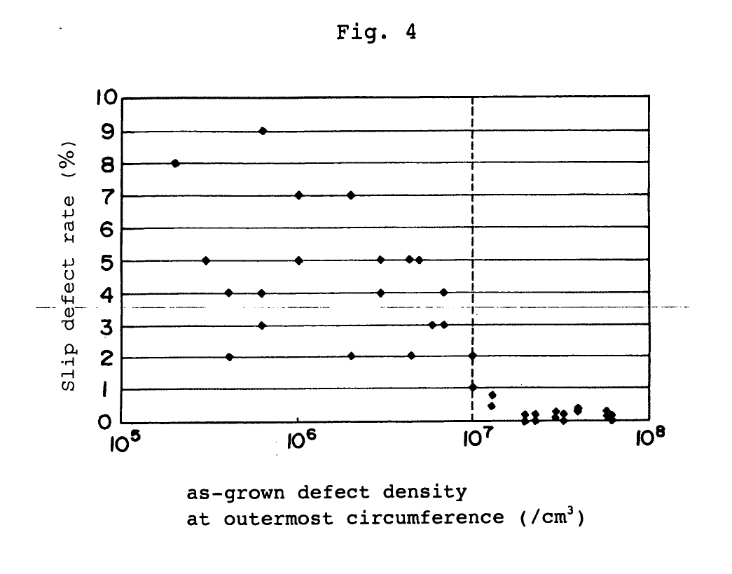

FIGS. 3 and 4 show a relationship between the minimum as-grown defect density in the case where the silicon single crystal having the oxygen concentration of 0.9×10¹⁸ atoms/cm³ is grown and R-OSF's exist in the wafer plane, that is the as-grown defect density at the outermost circumference, and a slip generation frequency at the time of annealing.

Considering that there are variety of embodiments of the high temperature heat treatment (annealing treatment) because a depth area required in device production varies according to use of the wafer, FIG. 3 shows the graph in the case where the hydrogen annealing treatment is carried out by way of a batch process in a vertical furnace at a temperature of 1200° C., for one hour, further FIG. 4 shows the graph in the case where the high temperature rapid acceleration Ar annealing treatment (heat treatment carried out at a temperature of 1000° C. or more, for a short period of time in the order of seconds) is carried out by way of a sheet-fed process.

In addition, the slip generation frequencies of these are measured with a wafer surface inspection apparatus (SP1, manufactured by KLA Tencor Corporation).

As can be seen from the graphs in FIGS. 3 and 4, in either case, the higher the as-grown defect density of the outermost circumference is, the lower the slip generation frequency at the time of annealing is, and it has been found that similar effects are obtained in the various embodiments of the high temperature heat treatment.

In particular, the effect of preventing the wafer surface from cracking is also obtained in a high-speed rise-and-fall high-temperature heat treatment, such as flash lamp annealing.

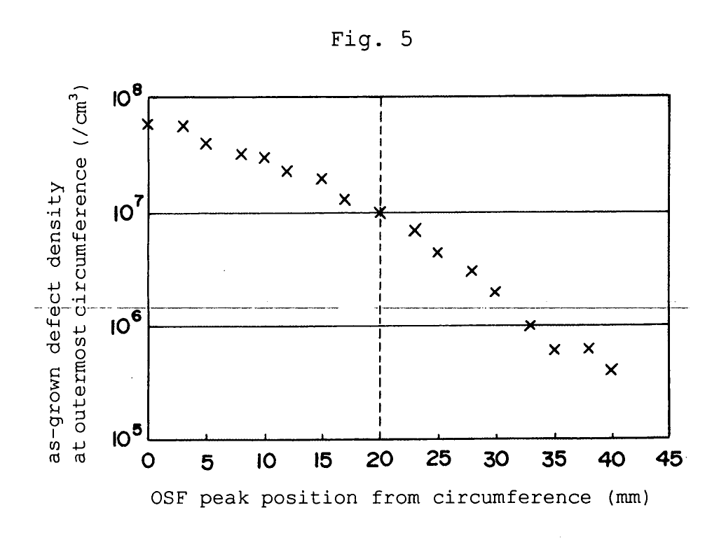

Further, FIG. 5 shows a relationship between the as-grown defect densities at the outermost circumference and the R-OSF peak positions.

As shown in the graph of FIG. 5, when the R-OSF peak position is within 20 mm of the circumference, the as-grown defect density of the outermost circumference is 1×10⁷/cm³ or more, and it can be seen that the present invention is effective for inhibiting slip with reference to the graphs of FIGS. 3 or 4.

The higher the oxygen concentration in the silicon single crystal is, the higher the as-grown defect density is. Thus, the oxygen concentration of 0.9×10¹⁸ atoms/cm³ or more provides the slip inhibition effect similar to the above.

Therefore, in the present invention, the conditions at the time of growing the silicon single crystal are such that the oxygen concentration is 0.9×10¹⁸ atoms/cm³ or more, the R-OSF peak position is within 20 mm of the circumference, and the OSF's preferably exist up to the outermost circumference part of the wafer.

Further, as described above, in order to cause the R-OSF peak position to be within 20 mm of the circumference and the OSF's to exist up to the outermost circumference part of the wafer, it is preferable that v/G in the outermost circumference of the wafer is 0.190 (mm²/(min.° C.)) or more according to heat transfer calculation.

What is claimed is:

1. A method of manufacturing a silicon wafer, wherein a silicon single crystal is grown under conditions where an oxygen concentration is 0.9×10¹⁸ atoms/cm³ or more and an oxidization induced stacking fault density is the maximum in an area within 20 mm of a wafer circumference, and an as-grown defect density in the wafer obtained by slicing said silicon single crystal is 1×10⁷/cm³ or more over the whole region of the wafer.

2. The method of manufacturing the silicon wafer as claimed in claim 1, wherein the oxidization induced stacking faults exist up to the outermost circumference part of the wafer in the case of growing said silicon single crystal.

3. The method of manufacturing the silicon wafer as claimed in claim 1, wherein a ratio v/G between a crystal pulling speed v (mm/min) and a temperature gradient G (mm/° C.) in a crystal orientation at the outermost circumference is 0.190 (mm²/(min.° C.)) or more when growing said silicon single crystal.

4. The method of manufacturing the silicon wafer as claimed in claim 1, wherein after mirror finish said silicon wafer is subjected to heat treatment at a temperature of 1000-1200° C. in a hydrogen or inactive gas atmosphere.

5. The method of manufacturing the silicon wafer as claimed in claim 4, wherein said heat treatment is a hydrogen annealing treatment at a temperature of 1000-1200° C.

6. The method of manufacturing the silicon wafer as claimed in claim 4, wherein said heat treatment is a high temperature rapid acceleration Ar annealing treatment at a temperature of 1000-1200° C.

7. A method of manufacturing a silicon wafer, comprising the steps of: growing a silicon single crystal by way of Czochralski method under conditions where an oxygen concentration is 0.9×10¹⁸ atoms/cm³ or more and an oxidization induced stacking fault density is the maximum in an area within 20 mm of a wafer circumference; mirror finishing the silicon wafer obtained by slicing said silicon single crystal; and heat treating said silicon wafer at a temperature of 1000-1200° C. in a hydrogen or inactive gas atmosphere, wherein an as-grown defect density is 1×10⁷/cm³ or more over the whole region of the wafer.

8. The method of manufacturing the silicon wafer as claimed in claim 7, wherein the oxidization induced stacking faults exist up to the outermost circumference part of the wafer in the case of growing said silicon single crystal.

9. The method of manufacturing the silicon wafer as claimed in claim 7, wherein a ratio v/G between a crystal pulling speed v (mm/min) and a temperature gradient G (mm/° C.) in a crystal orientation at the outermost circumference is 0.190 (mm²/(min.° C.)) or more when growing said silicon single crystal.

10. The method of manufacturing the silicon wafer as claimed in claim 7, wherein said heat treatment is a hydrogen annealing treatment at a temperature of 1000-1200° C.

11. The method of manufacturing the silicon wafer as claimed in claim 7, wherein said heat treatment is a high temperature rapid acceleration Ar annealing treatment at a temperature of 1000-1200° C.

12. The method of manufacturing the silicon wafer as claimed in claim 2, wherein a ratio v/G between a crystal pulling speed v (mm/min) and a temperature gradient G (mm/° C.) in a crystal orientation at the outermost circumference is 0.190 (mm²/(min.° C.)) or more when growing said silicon single crystal.

13. The method of manufacturing the silicon wafer as claimed in claim 8, wherein a ratio v/G between a crystal pulling speed v (mm/min) and a temperature gradient G (mm/° C.) in a crystal orientation at the outermost circumference is 0.190 (mm²/(min.° C.)) or more when growing said silicon single crystal.
